(19) United States
(12) Patent Application Publication
(10) Pub. No.: US 2024/0084636 A1
(43) Pub. Date: Mar. 14, 2024

(54) MOTORIZED HINGE LIFT FOR PVD CHAMBERS

(71) Applicant: Advanced Refurbishment Technologies LLC d/b/a ARTSemi LLC, Austin, TX (US)

(72) Inventors: Christopher William Lewis, Austin, TX (US); Timothy H. Ickes, Manchaca, TX (US)

(73) Assignee: Advanced Refurbishment Technologies LOLC d/b/a ARTSemi LLC, Austin, TX (US)

(21) Appl. No.: 18/368,448

(22) Filed: Sep. 14, 2023

Related U.S. Application Data
(60) Provisional application No. 63/406,508, filed on Sep. 14, 2022.

(51) Int. Cl. E05F 15/611; C23C 14/00

(52) U.S. Cl. CPC E05F 15/611; C23C 14/00; E05Y 2400/36; E05Y 2400/818; E05Y 2900/60

(57) ABSTRACT

This disclosure relates to motorized hinge-lift system designed for integration and use with physical vapor deposition (PVD) chambers, enabling efficient and precise control of the chamber's lid assembly. PVD technology plays a critical role in thin film deposition processes for various industries, including semiconductor manufacturing, optical coatings, and advanced materials research. The proposed motorized hinge-lift systems contemplated and discussed herein significantly enhances the functionality and performance of PVD chambers by addressing key challenges associated with their operation. Among other related benefits, embodiments of such motorized hinge-lift system may provide for simple retrofitting of existent PVD chambers, and may allow seamless and reliable lid lifting and lid lowering operations, thereby minimizing the risk of operator injury or damage to sensitive substrates within the chamber or to the PVD chamber itself.

### PRIORITY STATEMENT UNDER 35 U.S.C. § 119 & 37 C.F.R. § 1.78

This non-provisional application claims priority based upon prior U.S. Provisional Patent Application Ser. No. 63/406,508 filed Sep. 14, 2022, in the name of Christopher William Lewis entitled “MOTORIZED HINGE LIFE FOR PVD CHAMBERS,” the disclosures of which are incorporated herein in their entirety by reference as if fully set forth herein.

### BACKGROUND OF THE INVENTION

There are estimated over 10,000 of the 200 mm Endura chambers in the world being utilized at this time. Endura chambers utilize pneumatic springs to assist with managing the weight of their lids during the opening and closing of the chambers. There are some configurations of such chambers with lid assemblies which weigh over 200 pounds and require one person to climb up onto the mainframe of the system and lift the chamber lid to open it, while a second person places the safety lift pins into the hinge assembly to hold the chamber lid either 90 degrees, upright, or 180 degrees, flat, for removing the target assembly. Over time, the weight of the lid assemblies can overpower the pneumatic springs, causing them to fail. Both the need to manually deal with the weighty lid assemblies, and the propensity for the chambers' pneumatic springs to break resulting therefrom, create an unsafe environment for technicians, especially those of smaller stature (which may disproportionately affect women), or who are less physically capable (e.g., older technicians, or ones with physical impairments or disabilities).

Accordingly, it may prove beneficial for there to be systems that reduce the difficulty of opening and closing the lids of these chambers resulting from their high weight. For example, such a system may enable a single person to operate a chamber that previously required two, or may simply put less physical strain on a single operator. Additionally, is likely that the use of such devices will reduce the frequency of drops or other violent actions that could result from a less controlled closing or opening of the chambers, which could put stress on the system's hinges, damage the interior surfaces of the chamber due to collision, or even crush the fingers of the person operating the chamber. In any event, such system for reducing the difficulty of opening and closing chamber lids may the result is lower operating costs and fewer physical hazards.

Additionally, pre-existing PVD chambers generally have a motor attached to a magnet assembly, which is used to spin the magnet assembly in a continuous fashion during the chamber's operation. An interlock ensures that the chamber cannot be run if the magnet is not spinning. However, while the RPM of the magnet assembly can have an impact on the process results PVD chambers generally do not have a means for easily indicating magnet assembly RPM (there may be light indicators that show whether the assembly is, or is not, spinning, but generally nothing shows the actual magnet assembly RPM, much less do so in near-real time). Accordingly, benefits may be achieved by providing a system which may monitor, display, and control the RPM of the chamber's magnet assembly in near-real time.

### SUMMARY OF THE INVENTION

The present disclosure relates to motorized hinge-lift systems for reducing the physical effort required to open the lid assembly of physical vapor deposition (“PVD”) chambers, many of which have grown physically in both size and weight and technical complexity.

The present disclosure teaches various embodiments of a motorized hinge-lift system which may be integrated into a hinge system of existing PVD chambers, and which may include buttons that may be used to engage the motor of the motorized hinge-lift system, causing it to open or close the lid of the PVD chamber on which it is installed.

Additionally, embodiments of motorized hinge-lift system may provide for further functional enhancement of existing PVD chambers, including the ability to display and perform ongoing measurement and adjustment of an RPM of a magnet in the PVD chamber with which the motorized hinge-lift system is integrated.

Further, embodiments of motorized hinge-lift systems taught herein may be used to retrofit existing PVD chambers so that they may be operated more easily. In such embodiments, the motorized hinge-lift system may be installed onto the hinge system of an existing PVD chamber a via supplied locking pin. Set-screws along with a platen and pin may further enable a safe and secure method for attaching a motorized hinge-lift system to provide the function of opening and closing the chamber with the motorized hinge-lift system.

The foregoing has outlined rather broadly certain aspects of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### DESCRIPTION OF THE DRAWINGS

For a more complete understanding of the present invention, and the advantages thereof, reference is now made to the following descriptions taken in conjunction with the accompanying drawings, in which:

FIG. 1 provides a perspective view of a standard PVD chamber known in the art without any modifications to its hinge system.

FIG. 2 provides a profile view of an exemplary embodiment of a motorized hinge-lift system.

FIG. 3 shows an exploded view of the exemplary embodiment of a motorized hinge-lift system as depicted in FIG. 2.

FIG. 4 provides a perspective view of an exemplary embodiment of a motorized hinge-lift system with the housing removed.

FIG. 5 depicts an exemplary embodiment of a motorized hinge-lift system installed on an exemplary PVD chamber.

FIG. 6 depicts an embodiment of a PVD chamber retrofitted with an embodiment of a motorized hinge-lift system that is shown in cross-section.

FIG. 7 provides a perspective view of an exemplary embodiment of a motorized hinge-lift system with its housing removed, installed on an exemplary PVD chamber.

FIG. 8 provides a side view of an exemplary embodiment of a motorized hinge-lift system installed on an exemplary PVD chamber, wherein the lid of the PVD chamber is in the closed position.

FIG. 9 provides a side view of an exemplary embodiment of a motorized hinge-lift system installed on an exemplary PVD chamber, wherein the lid of the PVD chamber is in a 90-degree open position.

FIG. 10 provides a side view of an exemplary embodiment of a motorized hinge-lift system installed on an exemplary PVD chamber, wherein the lid of the PVD chamber is in a 180-degree open position.

### DETAILED DESCRIPTION

The present invention is directed to improved systems and apparatuses for, among other things, Endura Chamber hinge lift. The configuration and use of the presently preferred embodiments are discussed in detail below, wherein the same components are referred to by the same numbering across the associated Figures. It should be appreciated, however, that the present invention provides many applicable inventive concepts that can be embodied in a wide variety of contexts other than Endura Chamber hinge lift. Accordingly, the specific embodiments discussed are merely illustrative of specific ways to make and use the invention, and do not limit the scope of the invention.

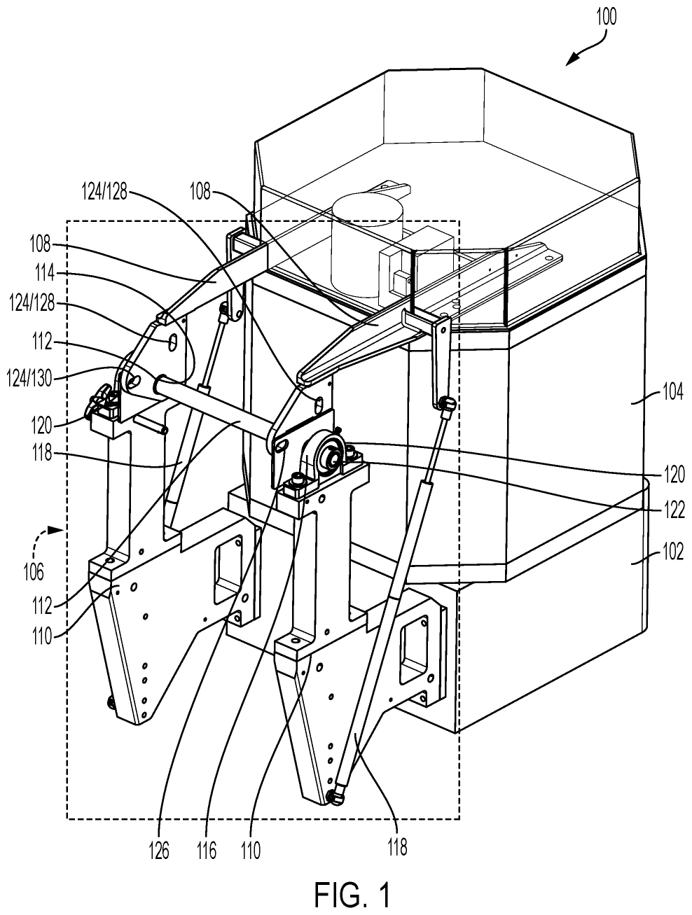

Referring now to FIG. 1, FIG. 1 provides a perspective view of a standard PVD chamber, chamber 100, without any modifications to its hinge system. Chamber 100 comprises body 102, lid 104, and hinge system 106 comprising a set of lid-leaves 108 a set of body-leaves 110, and a pintle 112. Each lid-leaf 108 may comprise a first end rigidly connected to lid 104 and a second end extending from lid 104 to a hinge location and comprising aperture 114. Each body-leaf 110 may comprise a first end rigidly attached to the body 102 and a second end extending from body 102 to the hinge location and comprising aperture 116. Apertures 114 of lid-leaves 108 and apertures 116 of body-leaves 110 may be positioned relative to one another such that they align along an axis of rotation of the hinge system (the “hinge axis”), thereby operating as knuckles of the hinge and together forming the barrel of hinge system 106. Pintle 112 may be positioned such that it travels along the hinge axis and through apertures 114 and 116, such that lid-leaves 108 may rotate about pintle 112 and, correspondingly, about the hinge axis relative to body-leaves 110.

Hinge system 116 of chamber 100 may further comprise one or more pneumatic pistons 118 and one or more bearing housings 120. Pneumatic pistons 118 may be connected between a lid-leaf 108 and a body-leaf 110 on the same side of chamber 100 and be configured such that pistons 118 operate to resist downward motion of lid 104. Bearing housings 120 may be fixedly attached to one of lid-leaves 108 or body-leaves 110 (in the embodiment depicted in FIG. 1 bearing housings 120 are shown fixed to body-leaves 110) and may comprise a bearing ring 122 which may be positioned along the hinge axis in alignment with apertures 114 and apertures 116. In such embodiments, pintle 112 may extend through bearing rings 122 of bearing housings 120 in addition to apertures 114 of lid-leaves 108 and apertures 116 of body-leaves 110.

In embodiments, the end of a lid-leaf 108 extending from lid 104 may, in addition to aperture 114, comprise one or more locking apertures 124 which may be offset from the hinge axis and spaced apart from aperture 114. Similarly, in embodiments, the end of a body-leaf 110 extending from body 102 may also comprise a locking aperture 126 which may be offset from the hinge axis and spaced apart from aperture 116. In such embodiments, lid-leaf locking apertures 124 and body-leaf locking aperture 126 may be positioned such that body-leaf locking aperture 126 may align with each of the one or more lid-leaf locking apertures 124 when lid 104 is at specific positions along the arc of motion through which it travels during the lid-opening and lid-closing processes. When, during the rotation of lid 104 about pintle 112, one of the lid-leaf apertures 124 align with body-leaf locking aperture 126, a locking pin (not shown) may be inserted through both body-leaf locking aperture 126 and the lid-leaf locking aperture aligned therewith in order to lock lid 104 in a static position. In the particular embodiment depicted in FIG. 1, each of lid-leaves 108 comprise two lid-leaf locking apertures 124, wherein lid-leaf locking aperture 128 is positioned such that it may be used to lock lid 104 in a 90 degree (i.e., vertical) open position, and lid-leaf locking aperture 130 is positioned such that it may be used to lock lid 104 in a 180 degree (horizontal) open position.

Pre-existing PVD chambers, such as chamber 100, generally have a motor attached to a magnet assembly, which may drive the magnet assembly so that the magnet spins in a continuous fashion during operation of the chamber, and an interlock which ensures that the chamber cannot be run if the magnet is not spinning. The RPM of the magnet may be increased or decreased via operation of a control on the chamber.

As previously discussed hereinabove, there are several issues with PVD chambers, such as unmodified PVD chamber 100 of FIG. 1, which may be addressed by the addition of a motorized hinge-lift system, as contemplated by this disclosure.

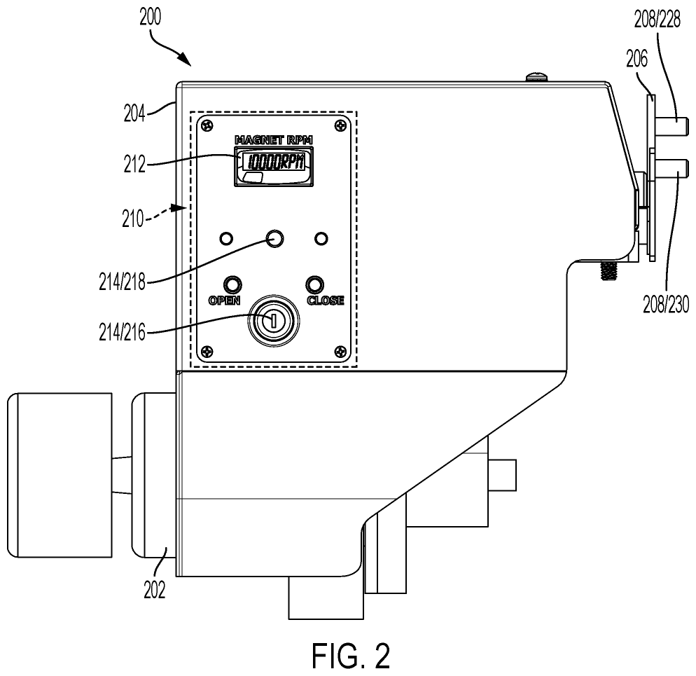

FIG. 2 provides a profile view of an exemplary embodiment of a motorized hinge-lift system, system 200. Motorized hinge-lift system 200 may be configured specifically to be attached to and actuate a PVD chamber hinge system, such as hinge system 106 of unmodified PVD chamber 100 from FIG. 1.

Motorized hinge-lift system 200 may comprise a motor 202 retained within a housing 204, and an engagement plate 206 comprising one or more pins 208 which may be configured to be attached to a leaf of a hinge system of a PVD chamber, such as hinge system 106 of unmodified PVD chamber 100 from FIG. 1. The manner in which motorized hinge-lift system 200 may be integrated into PVD chamber, such as unmodified PVD chamber 100, will be depicted in subsequent figures and discussed in detail hereinbelow.

Additionally, in embodiments, such as that depicted in FIG. 2, motorized hinge-lift system, system 200 may comprise a user interface panel 210 which may comprise a display 212 and one or more input devices 214, wherein the display is configured to receive information from a PVD chamber, such as chamber 100 of FIG. 1, and display said information to an operator of motorized hinge-lift system 200. In embodiments, one or more of display 212 and input devices 214 may be located on, or extend beyond, an exterior surface of housing 204.

In embodiments, the information that display 212 is configured to receive from the PVD chamber and to show on the display comprises an RPM of a magnet in the chamber. In such embodiment, one of input devices 214 may comprise an RPM control input 218, which may be configured to receive input from an operator and control an RPM of a magnet in the associated PVD chamber responsive thereto. Additionally, one or more of input devices 214 may comprise a lid position input 216, which may be configured to receive input from an operator and cause motor 202 to actuate in one or more of a first direction corresponding to the opening of the lid of an associated PVD chamber, and in a second direction, opposite the first direction, corresponding to the closing of the lid of an associated PVD chamber responsive thereto. In embodiments, input devices 214 may comprise one or more of a potentiometer, multi-position selector switch, a button, a touch-screen interface, or any other suitable input mechanism known in the art.

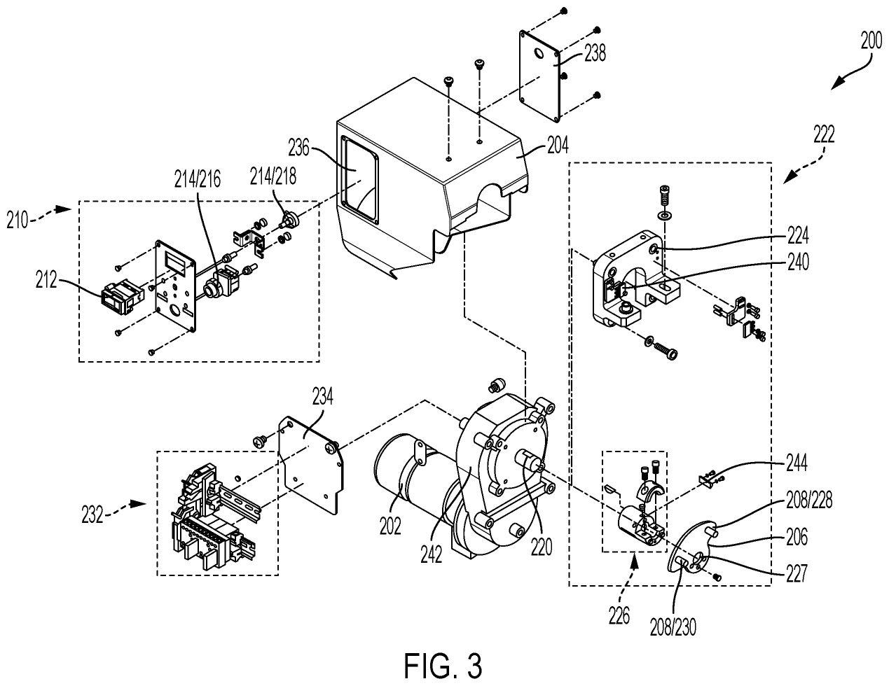

FIG. 3 shows an exploded view of the exemplary embodiment of a motorized hinge-lift system as depicted in FIG. 2. As can be seen in FIG. 3, in addition to motor 202, housing 204, engagement plate 206, and user interface panel 210, embodiments of a motorized hinge-lift system, such as system 200, may additionally comprise a gearbox 242, an output shaft 220, and a coupling assembly 222.

In such embodiments, gearbox 242 may be connected between motor 202 and output shaft 220 and may permit for the system to apply a gear ratio reduction when applying forces generated by motor 202 to output shaft 220. The gear reduction ratio of gearbox 242 may be any ratio suitable to perform the desired actuation of lid 104.

Coupling assembly 222 may comprise mounting bracket 224, coupling 226, and engagement plate 206. Coupling assembly 226 may be configured to permit engagement between motorized hinge-lift system 200 and the hinge system of a PVD chamber, such as hinge system 106 of PVD chamber 100 from FIG. 1.

Mounting bracket 224 may be configured to fixedly attach motor 202 or gearbox 242 of motorized hinge-lift system 200 to one of a lid-leaf 108 or a body-leaf 110 of hinge system 106 of an associated PVD chamber so that the rest of motorized hinge-lift system 200 to be installed thereon.

A first end of coupling 262 may be mechanically affixed to the end of output shaft 220 not connected to motor 202 or gearbox 242. A second end of coupling may be mechanically affixed to engagement plate 206 such that each of coupling 262 and engagement plate 206 corotate with output shaft 220 responsive to the operation of motor 202. Coupling may further be configured to receive and fixedly engage with an end of pintle 112 extending beyond apertures 114 of lid-leaf 108 and 116 of 110.

Engagement plate 206 may comprise one or more pins 208 and aperture 227, wherein aperture 227 is sized and located so as to permit pintle 112 to be passed therethrough and received by coupling 226. Pins 208 may comprise a first pin 228 which may be positioned and configured to align with and be inserted into, and thereby engage with, lid-leaf locking aperture 128, and a second pin 230 which may be positioned and configured to align with and be inserted into, and thereby engage with, lid-leaf locking aperture 130.

Embodiments of motorized hinge-lift system, such as system 200 may additionally comprise one or more limit switches 240, which may be configured such that when activated they will cause motorized hinge-lift system 200 to cut power to motor 202 and thereby stop its further actuation in the direction in which it was operating when the lid 104 is in a particular position. Limit switches 240 may be located on one or more sides of coupling 226 and may be attached to and supported by mounting bracket 224. Limit switches may be positioned and configured such that they are activated by extension 244, which may be attached to and extend from an outer surface of coupling 226, once it has rotated to a predetermined lid limit position beyond which lid 104 should not move, such as, for example, 0 and 180 degrees. In embodiments, activation of a limit switches 240 may cause corresponding indicators on the user interface panel 210 to light up for lid location verification.

Motorized hinge-lift system 200 may further comprise electronic control system 232. Electronic control system 232 may comprise relays and contactors that are configured to permit the supply or restriction of power to motor 202 responsive to predetermined conditions (e.g., the actuation of a lid position input 216, activation of a limit switch 240, etc.), and which may be communicatively connected to the user inputs 214, limit switches 240, and motor 202. Electronic control system 232 may be configured to control motor 202 responsive to its receipt of a lid actuation signal from lid position input 216. If the lid actuation signal comprises an “open signal” electronic control system 232 may control motor 202 to actuate in a first direction, resulting in the opening of a lid of the PVD chamber to which the hinge-lift system is attached. If the lid actuation signal comprises a “close signal” electronic control system 232 may control motor 202 to actuate in a second direction, opposite the first direction, resulting in the closing of a lid of the PVD chamber to which the hinge-lift system is attached. Electronic control system 232 may be mounted inside of housing 204 along with motor 202 using mounting plate 234, which may be used to support and attach electronic control system 232 to motor 202, gearbox 242, or housing 204.

In embodiments, one of the electronic control system 232 or the user input panel 210 may comprise a tachometer that may be communicatively connected to a magnet rotation sensor interlock and an RPM controller of the chamber on which it is installed, via a suitable means of data transmission, and configured to permit an RPM of the chamber's magnet assembly on display 212. In such embodiments, the system may be configured to receive one or more of an RPM signal from the interlock of the PVD chamber on which the motorized hinge-lift system is installed, an RPM modulation signal from RPM control input 218, and an open signal and a close signal from lid position input 216. Additionally, the system may be configured to send instructions to display 212 to display an RPM of a magnet of an associated PVD chamber responsive to receipt of an RPM signal from the interlock of the associated PVD chamber. Such motorized hinge-lift system may be configured to transmit an RPM modulation signal to the RPM controller of the associated PVD chamber responsive to receiving an RPM modulation signal from RPM control input 218, wherein said RPM modulation signals contain instructions to increase or decrease the RPM of the magnet of the associated PVD chamber.

Embodiments of housing 204 may be sized and configured to cover a majority of motor 202 and the electrical components of user interface panel 210 and electronic control system 232. Such a configuration may be desirable for protection of the electrical components of electronic control system 232, the protection of operators from moving components of the hinge-lift system, such as the motor, and to reduce the likelihood of tampering with or fouling of the hinge lift-system. Additionally, housing 204 may comprise an opening 236 in one or more of its surfaces in which user interface panel 210 may be mounted.

In a preferred embodiment, housing 204 may comprise such an opening 236 on each of a first and a second side of housing 204 so that user interface panel 210 may be mounted on either side of housing 204. In such embodiments, motorized hinge-lift system 200 may further comprise a cover 238 which may be used to cover the opening 236 which is not being used for the mounting of user interface panel 210.

In embodiments, motor 202 may comprise a brake, which may be configured such that if the actuation of lid 106 about the hinge axis caused by motorized hinge-lift system 200 is stopped, brake may apply mechanical forces to resist the downward motion of lid assembly 104.

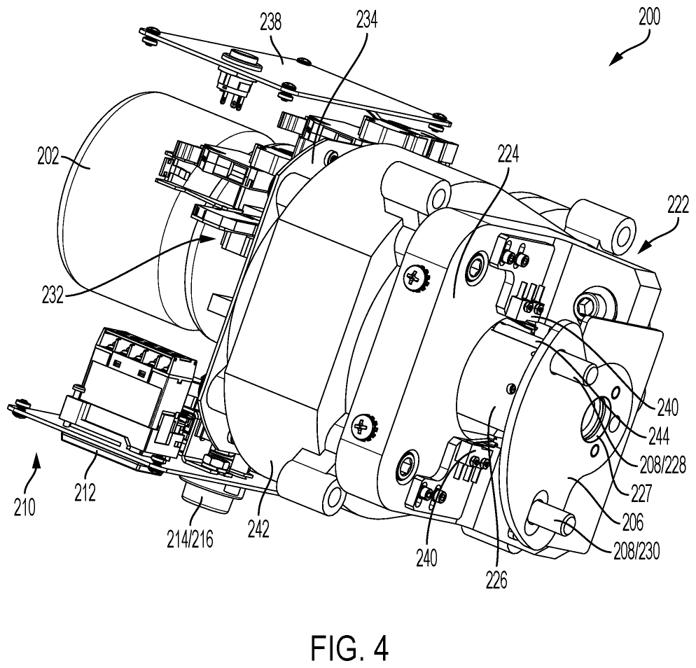

FIG. 4 provides a perspective view of an exemplary embodiment of a motorized hinge-lift system with the housing removed. This view depicts in greater detail how the components of motorized hinge-lift system 200 depicted in FIG. 3 may be assembled into an integrated unit.

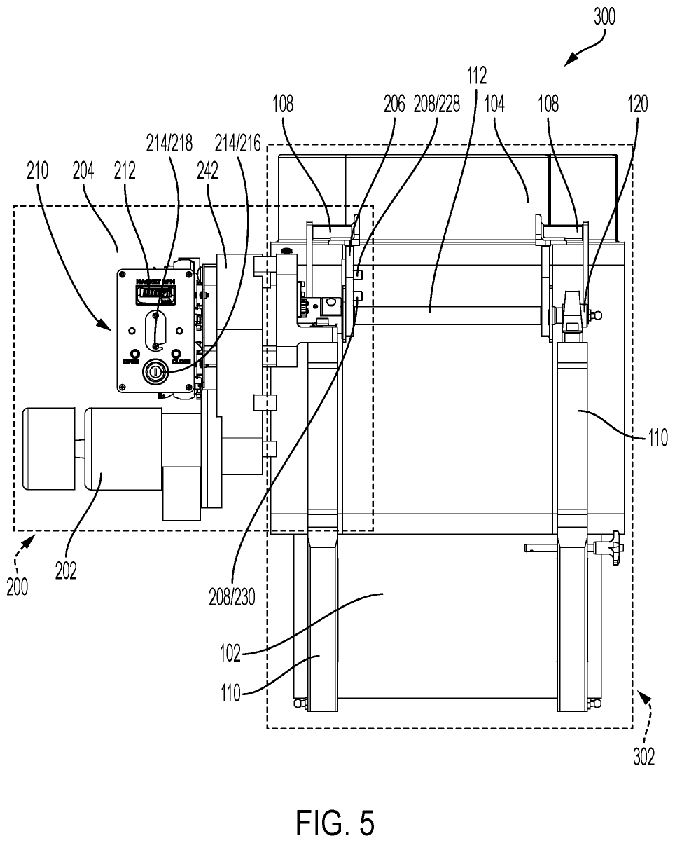

FIG. 5 depicts an exemplary embodiment of a retrofitted PVD chamber, chamber 300, comprising a modified hinge system 302, which may essentially be a modified version of the hinge system from a standard PVD chamber, such as hinge system 106 of chamber 100 from FIG. 1, and a motorized hinge-lift system 304, which may be substantially similar to motorized hinge-lift system 200 of FIGS. 2-4.

Modification of the hinge system 106 of standard PVD chamber 100 from FIG. 1 to a modified hinge system, such as modified hinge system 302, which is configured to accept instillation of a motorized hinge-lift system, such as motorized hinge lift system 200, may be achieved by selecting a side of chamber 100 on which motorized hinge-lift system is to be mounted. Removing the bearing housing 120 and the pneumatic piston 118 on the side of hinge system 106 to which motorized hinge-lift system 200 is to be mounted.

Once the hinge system 106 of a standard PVD chamber 100 has been so modified, resulting in a modified hinge system, such as modified hinge system 302, a motorized hinge-lift system, such as motorized hinge-lift system 200, may be attached thereto. Motorized hinge-lift system 200 may be mounted to modified hinge system 302 by fixedly attaching mounting bracket 224 to one of the lid-leaf 108 and the body-leaf 110 (in the embodiment depicted mounting bracket 224 is consistently depicted as being secured to body-leaf 110, but it may be affixed to either lid-leaf 108 body-leaf 110 as long as engagement plate 206 engages the other of the lid-leaf 108 or body-leaf 110 corresponding to the leaf so selected (i.e., if mounting bracket 224 is affixed to body-leaf 110, as depicted in the FIGs., then engagement plate may be configured to engage the corresponding lid-leaf 108 (as depicted); alternatively, if mounting bracket 224 is affixed to lid-leaf 108, then engagement plate may be configured to engage with the corresponding body-leaf 110).

When mounting bracket 224 is so attached to a leaf of the modified hinge lift system 302, engagement plate 206 should be positioned and configured such that the aperture 227 of engagement plate 206 may align with each of aperture 114 of lid-leaf 108, aperture 116 of body-leaf 110, pintle 112, and the hinge axis and such that the one or more pins 208 of engagement plate 206 may align with corresponding locking apertures 124 or 126, of the leaf to which the mounting bracket is not attached (i.e., with locking apertures 124 if mounting bracket 224 is attached to body-leaf 110, or with locking apertures 126 if mounting bracket 224 is attached to lid-leaf 108). When installed, pins 208 may be inserted into and mechanically engage with the locking apertures so selected.

Instillation of the motorized hinge-lift system 200 may further require that an end of pintle 112, which would have previously passed through the bearing ring 122 of the bearing housing 120 that was removed from the hinge system 106 during its conversion to modified hinge system 302, be passed through aperture 227 of engagement plate 206, after which it may be received by coupling 226 and fixedly secured thereto.

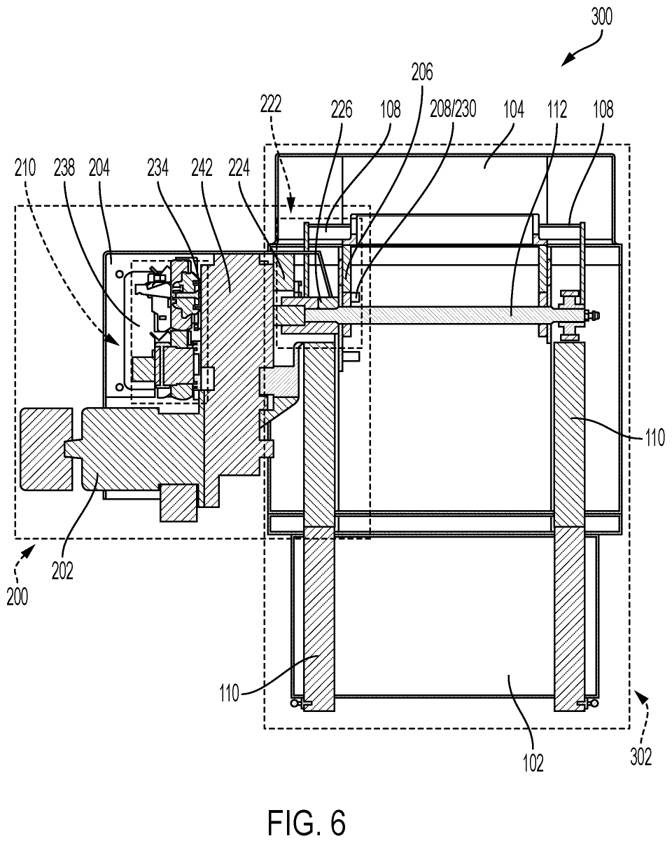

FIG. 6 depicts retrofitted PVD chamber 300 of FIG. 5, wherein motorized hinge-lift system 200 is shown in cross-section. In the cross-sectional view of hinge-lift system 200 electronic control system 210 can be seen mounted to a surface of motor 202 and positioned inside of housing 204.

This cross-sectional view of motorized hinge-lift system 200 provided in FIG. 6 additionally shows the interface between the components of modified hinge system 302 and those of coupling assembly 222. Specifically, pintle 112 may be seen passing though aperture 227 of engagement plate 206 and into coupling 226. Similarly, pin 208/230 can be seen extending from a surface of engagement plate 206 and passing through locking aperture 114 of lid-leaf 108. Different embodiments of coupling assembly 222, and in particular engagement plate 206, may be configured to various different designs ok known PVD chambers, which may provide for a motorized hinge-lift system to be installed on, and properly interface with, different designs of PVD chambers and PVD chamber hinge systems by swapping out different embodiment of coupling assembly 222, and in some cases, just engagement plate 206.

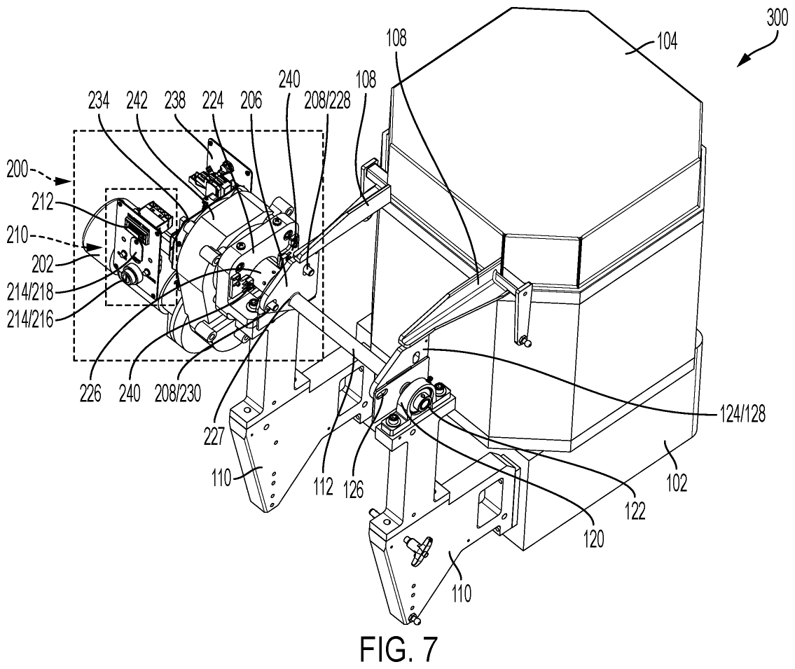

FIG. 7 provides a perspective view of an exemplary embodiment of a motorized hinge-lift system installed on an exemplary PVD chamber consistent with retrofitted PVD chamber 300 of FIG. 5, but wherein housing 204 is not shown. FIG. 7 may provide for a better view of the way in which motorized hinge-lift system 200 may be installed onto modified hinge system 302 in order to form a retrofitted PVD chamber, such as chamber 300. In FIG. 7 displays how mounting bracket 224 may be used to fixedly attached to motor 202 to body-leaf 110 and may shaped so that it does not impede the passage of output shaft 220, coupling 226, or pintle 112 thereby. Pintle 112 may be seen passing through aperture 227 in engagement plate 206 so that it may be accepted by and engage with coupling 226, and thereby be fixedly coupled with output shaft 220. Similarly, the pins 208 of engagement plate 206 can be seen passing through locking apertures 124 and thereby engaging with lid-leaf 108; and more specifically, pin 228 may be seen passing through locking aperture 128 and pin 230 may be seen passing through locking aperture 130.

Engagement plate 206 may be fixedly coupled with output shaft 220 such that rotation of output shaft 220 in a first direction causes pins 208 to apply a torque on the lid-leaf 108 with which engagement plate 206 is engaged, wherein said torque is offset from the hinge axis such that it will cause the engaged lid-leaf 108, and therefore lid 104 to which lid-leaf 108 is fixedly attached, to rotate about said hinge axis in the first direction. Similarly, rotation of output shaft 220 in a second direction (opposite the first direction) causes pins 208 to apply a torque on the engaged lid-leaf 108 such that it and the attached lid 104 will rotate about said hinge axis in the second direction.

The embodiment of motorized hinge-lift system 200 depicted in FIG. 7 is shown with the housing 104 removed. The removal of housing 104 in this figure helps depict the manner in which mounting plate 234 may be mounted to motor 202; and how in embodiments, mounting plate 234 may be used to support user interface panel 210 on a first side of the motorized hinge-lift system 200 and cover 238 on the side of motorized hinge-lift system 200 opposite user interface panel 210.

Some preferred embodiments of motorized hinge-lift systems, such as system 200, are designed such that they may be configured for instillation on either side of the hinge system of a chamber with the same bill of materials provided. Furthermore, the inclusion of two openings 236 on opposite sides of housing 204, the ability for user interface panel 210 to be functionally mounted in either of said openings 236 in housing 204, and the inclusion of cover 238 for covering the opening in which user interface panel 210 is not mounted, allows for user interface panel 210 and cover 238 each to be swapped between openings 236 so that user interface panel 210 may be accessed from whichever side of motorized hinge-lift system is convenient for its operator.

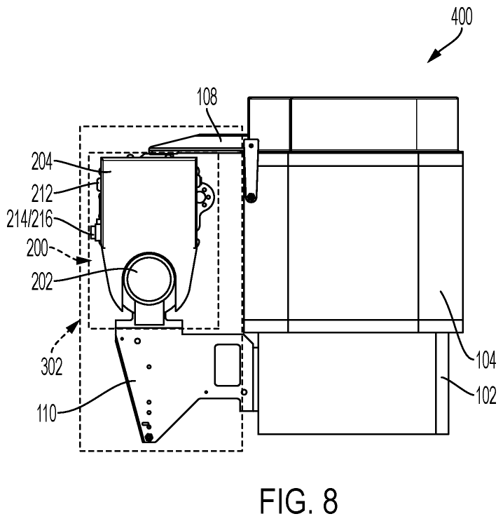

FIG. 8 provides a side view of an exemplary embodiment of a PVD chamber including a motorized hinge-lift system, namely motorized PVD chamber 400, wherein the lid 104 of motorized PVD chamber 400 is in the closed position.

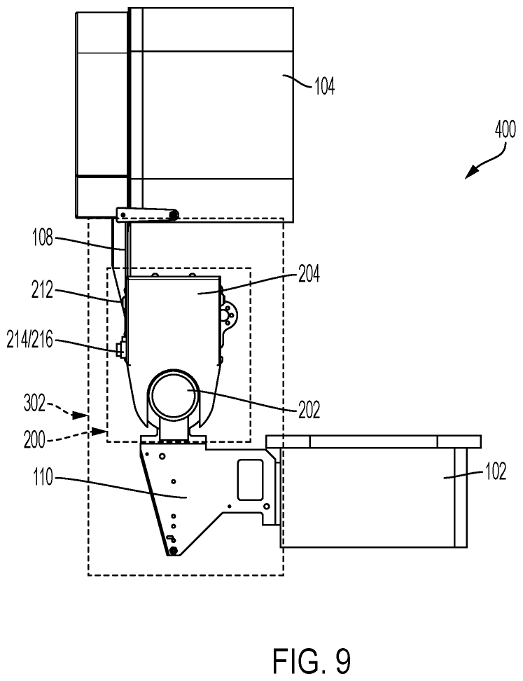

FIG. 9 provides a side view of motorized PVD chamber 400 of FIG. 8, wherein the lid 104 of motorized PVD chamber 400 is in a 90-degree open position.

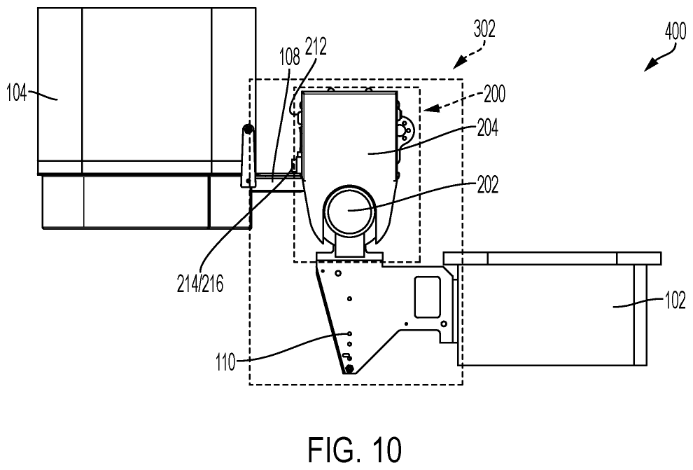

FIG. 10 provides a side view of motorized PVD chamber 400 of FIG. 8, wherein the lid 104 of motorized PVD chamber 400 is in a 180-degree open position.

An operator of motorized PVD chamber 400 may use lid position input 216 to activate motor 202, causing motor 202 to drive output shaft 220 in either of a first direction consistent with the opening of lid 104, or a second, opposite, direction consistent with the closing of lid 104.

As discussed hereinabove, embodiments of motorized hinge lift system 200 may be used to retrofit the hinge system of pre-existing PVD chambers. Accordingly, embodiment of motorized hinge lift system 200 may be configured as a kit for retrofitting such chambers.

While the present system and method has been disclosed according to the preferred embodiment of the invention, those of ordinary skill in the art will understand that other embodiments have also been enabled. Even though the foregoing discussion has focused on particular embodiments, it is understood that other configurations are contemplated. In particular, even though the expressions “in one embodiment” or “in another embodiment” are used herein, these phrases are meant to generally reference embodiment possibilities and are not intended to limit the invention to those particular embodiment configurations. These terms may reference the same or different embodiments, and unless indicated otherwise, are combinable into aggregate embodiments. The terms “a”, “an” and “the” mean “one or more” unless expressly specified otherwise. The term “connected” means “communicatively connected” unless otherwise defined.

When a single embodiment is described herein, it will be readily apparent that more than one embodiment may be used in place of a single embodiment. Similarly, where more than one embodiment is described herein, it will be readily apparent that a single embodiment may be substituted for that one device.

In light of the wide variety of methods for opening and closing PVD chambers known in the art, the detailed embodiments are intended to be illustrative only and should not be taken as limiting the scope of the invention. Rather, what is claimed as the invention is all such modifications as may come within the spirit and scope of the following claims and equivalents thereto.

None of the description in this specification should be read as implying that any particular element, step or function is an essential element which must be included in the claim scope. The scope of the patented subject matter is defined only by the allowed claims and their equivalents. Unless explicitly recited, other aspects of the present invention as described in this specification do not limit the scope of the claims.

To aid the Patent Office and any readers of any patent issued on this application in interpreting the claims appended hereto, the applicant wishes to note that it does not intend any of the appended claims or claim elements to invoke 35 U.S.C. 112(f) unless the words “means for” or “step for” are explicitly used in the particular claim.

1. A hinge-lift system for a PVD chamber comprising:
1.1. a motor;
1.2. an electronic control system configured to control the motor responsive to actuation of a lid position input;
1.3. a coupling assembly configured to fixedly attach the motor to a first leaf of a hinge system of the PVD chamber, and to interface between an output shaft of the motor and a second leaf of the hinge system, wherein one of the first leaf and the second leaf is fixedly attached to a lid of the PVD chamber, and the other of the first leaf and the second leaf is fixedly attached to a body of the PVD chamber.

2. The hinge-lift system of claim 1, wherein the coupling assembly comprises:
2.1. a mounting bracket configured to fixedly attach the motor to the first leaf;
2.2. an engagement plate comprising a pin wherein the pin is configured to align with and be inserted into a locking aperture in the second leaf; and
2.3. a coupling configured to fixedly attach the output shaft of the motor to the engagement plate such that the engagement plate co-rotates with the output shaft responsive to operation of the motor.

3. The hinge-lift system of claim 1, wherein the electronic control system is configured to be communicatively connected to an interlock and an RPM controller of the PVD chamber and to receive an RPM signal therefrom, and further comprising a user input panel comprising:
3.1. the lid position input,
3.2. a display configured to receive and display an RPM from the electronic control system based on the RPM signal in near-real time,
3.3. an RPM control input configured to transmit an RPM modulation signal to the electronic control system responsive to its actuation, and wherein the electronic control system is further configured to transmit the RPM modulation signal to RPM controller.

4. The hinge-lift system of claim 1, further comprising a housing disposed about at least a portion of the motor and a portion of the electronic control system, wherein the housing comprises an opening configured to support the user input panel such that the lid position input, the display, and the RPM control input may be accessed from outside of the housing.

5. The hinge-lift system of claim 3, wherein the housing comprises a second opening configured to support the user input panel such that the lid position input, the display, and the RPM control input may be accessed from outside of the housing, wherein the second opening is located on a different side of the housing than the opening, and further comprising a cover configured to occlude one of the opening and the second opening which is not supporting the user input panel.

6. A motorized hinge-lift system kit for retrofitting a PVD chamber having a hinge assembly, comprising:
6.1. a motor:
6.2. an output shaft configured to be driven by the motor;
6.3. a gearbox comprising a gear reduction ratio, coupled between the motor and the output shaft;
6.4. a coupling assembly comprising:
6.4.1. a mounting bracket configured to be fixedly attached to at least one of the motor and the gearbox, and to permit the motorized hinge-lift system kit to be attached to and supported by the hinge assembly;
6.4.2. an engagement plate configured to engage a leaf of the hinge system at a point non-coaxial with an axis of rotation of the output shaft;
6.4.3. a coupling configured to connect to and extend between the engagement plate and the output shaft such that engagement plate and coupling co-rotate with the output shaft responsive to operation of the motor, and to receive and secure an end of a pintle of the hinge system;
6.5. lid position input;
6.6. an electronic control system communicatively connected to the motor and the lid position input and configured to permit and restrict power from being supplied to the motor responsive to actuation of the lid position input; and
6.7. a housing disposed about the electronic control system and a portion of the motor, and comprising an opening configured to permit access to lid position input from outside of the housing.

7. A kit for retrofitting a PVD chamber of claim 6, further comprising a user interface panel configured to be inserted into and supported by the opening, and to thereby occlude the opening, wherein the user interface panel comprises the lid position input a display configured to receive and display an RPM of a magnet assembly from the PVD chamber and an RPM control input configured to control the RPM of the magnet assembly.

8. The kit for retrofitting a PVD chamber of claim 7, further comprising a cover, and wherein the housing further comprises a second opening opposite the first opening, and wherein the user interface panel is configured to be selectively inserted into and supported by either the opening or the second opening such that the lid position input, display, and RPM control input may be accessed from outside of the housing, and wherein the cover is configured to selectively cover whichever of the opening and the second opening does is not supporting the user interface panel.

9. The kit for retrofitting a PVD chamber of claim 6, wherein the engagement plate further comprises a pin extending from a surface thereof, said pin is configured to be received by a locking aperture in the leaf.

10. The kit for retrofitting a PVD chamber of claim 6, further comprising a mounting plate configured to connect to one of the motor, the gearbox, and an interior surface of the housing and to support at least a portion of the electronic control system.

11. The kit for retrofitting a PVD chamber of claim 7, further comprising a communication means configured to connect the electronic control system to at least one of a magnet RPM controller and an interlock of the PVD chamber.

12. A kit for retrofitting a PVD chamber of claim 11, wherein the electronic control system is configured to transmit an RPM modulation signal to the RPM controller responsive to receipt a signal from the RPM control input.

13. A kit for retrofitting a PVD chamber of claim 11, wherein the electronic control system is configured to receive a signal from the interlock, to determine a magnet RPM based on the signal, and to transmit the magnet RPM to the display, and wherein the display is configured to display the magnet RPM responsive thereto in near-real time.

14. A method of retrofitting a PVD chamber comprising a body, a lid, and a hinge system connecting the body to the lid, wherein the hinge system comprises a first leaf mechanically connected to the body, a second leaf mechanically connected to the lid, and a pintle connecting the first leaf and the second leaf, about which the second leaf may rotate relative to the first leaf, said method comprising the steps of:
14.1. removing a bearing housing from a side of the hinge system;
14.2. removing a pneumatic piston form the side of the hinge system;
14.3. fixedly attaching a motor to a first leaf of the hinge system;
14.4. affixing an output shaft of the motor to the pintle via a coupling; and
14.5. mechanically engaging an engagement plate configured to corotate with the output shaft to the second leaf.

15. The method of retrofitting a PVD chamber of claim 14, wherein the PVD chamber further comprises an interlock and an RPM controller, and wherein said method further comprises the step of communicatively connecting an electronic control system to at least one of the interlock and the RPM controller, wherein the electronic control system is configured to receive an RPM of a magnet assembly of the PVD chamber from the interlock, and to control the RPM controller responsive to operator input.

16. A PVD chamber comprising:
16.1. a motorized hinge-lift system comprising:
16.1.1. a motor:
16.1.2. an output shaft configured to be driven by the motor;
16.1.3. a gearbox comprising a gear reduction ratio, coupled between the motor and the output shaft;
16.1.4. a coupling assembly comprising:
16.1.4.1. a mounting bracket configured to be fixedly attached to at least one of the motor and the gearbox, and to permit the motorized hinge-lift system kit to be attached to and supported by the hinge assembly;
16.1.4.2. an engagement plate configured to engage a leaf of the hinge system at a point non-coaxial with an axis of rotation of the output shaft;
16.1.4.3. a coupling configured to connect to and extend between the engagement plate and the output shaft such that engagement plate and coupling co-rotate with the output shaft responsive to operation of the motor, and to receive and secure an end of a pintle of the hinge system;
16.1.5. lid position input;
16.1.6. an electronic control system communicatively connected to the motor and the lid position input and configured to permit and restrict power from being supplied to the motor responsive to actuation of the lid position input.

17. The PVD chamber of claim 16, further comprising a communication means configured to connect the electronic control system to at least one of a magnet RPM controller and an interlock of the PVD chamber.

18. The PVD chamber of claim 17, further comprising a display configured to receive and display an RPM of a magnet assembly received from the interlock and an RPM control input configured to control the RPM of the magnet assembly via the RPM controller.

19. The PVD chamber of claim 18, wherein the electronic control system is configured to transmit an RPM modulation signal to the RPM controller responsive to receipt a signal from the RPM control input.

20. The PVD chamber of claim 17, wherein the electronic control system is configured to receive a signal from the interlock, to determine a magnet RPM based on the signal, and to transmit the magnet RPM to the display, and wherein the display is configured to display the magnet RPM responsive thereto in near-real time.
